(19) United States
(12) Patent Application Publication
(10) Pub. No.: US 2024/0032256 A1
(43) Pub. Date: Jan. 25, 2024

(54) AIR-CONDITIONING SYSTEM FOR DATA CENTER COMPUTER ROOM AND CONTROL METHOD THEREOF

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Zhenghua WANG, Zhangjiakou City (CN)

(21) Appl. No.: 18/224,072

(22) Filed: Jul. 20, 2023

(30) Foreign Application Priority Data
Jul. 25, 2022 (CN) 202210879741.6

(51) Int. Cl. H05K 7/20; F24F 11/65; F24F 11/83

(52) U.S. Cl. CPC H05K 7/2059; H05K 7/20836; F24F 11/65; F24F 11/83; F24F 2110/10

(57) ABSTRACT

Embodiments of the present disclosure provide an air-conditioning system for a data center computer room and a control method thereof, belonging to the technical field of heat dissipation of the data center computer room. The system includes an indoor evaporation circulation loop and an outdoor cooling circulation loop, where the indoor evaporation circulation loop includes an evaporator and an indoor side heat exchange fan. The outdoor cooling circulation loop includes the evaporator, an outdoor side heat exchange fan, a wet-film cooling cooler, a condenser, an intercooler, a low-pressure stage compressor, a high-pressure stage compressor, a one-way valve, and a refrigerant pipeline. The system has good refrigeration effect, can accurately adjust temperature of the data center computer room and save energy.

### CROSS-REFERENCE TO RELATED APPLICATION

This application claims priority to Chinese Patent Application No. 202210879741.6, titled “AIR-CONDITIONING SYSTEM FOR DATA CENTER COMPUTER ROOM AND CONTROL METHOD THEREOF” and filed to the China National Intellectual Property Administration on Jul. 25, 2022, the entire contents of which are incorporated herein by reference.

### TECHNICAL FIELD

The present disclosure relates to the field of heat dissipation technology of a data center computer room, and more particularly, to an air-conditioning system for the data center computer room and a control method thereof.

### BACKGROUND

With the development of data center scale and integration, power density of server devices in a data center computer room is increasing day by day, and thermal density of the data center is getting higher and higher. In one aspect, power consumption of the data center computer room has increased significantly. In another aspect, cooling adjustment of the data center is not reasonable, such that it is unable to effectively dissipate heat for heating devices, which may lead to device shutdown.

Traditional data center computer rooms adopt mechanical refrigeration to solve the problem of heat dissipation of the data center computer rooms. The mechanical refrigeration consumes a lot of electric energy, even accounting for more than one third of total electricity consumption of the data center. At present, indirect evaporative cooling air-conditioning units are generally used in the market to mechanically refrigerate the data center computer rooms. In the process of refrigeration regulation, the indirect evaporative cooling air-conditioning units not only need to consume a lot of electric energy, but also use a lot of cooling water, and thus consumes a lot of water resources.

By studying the heat dissipation technology of the data center computer room, inventors of this patent application find that an existing air-conditioning system for the data center computer room has poor refrigeration effect, cannot accurately adjust a temperature of the data center computer room, and consumes a lot of energy sources.

### SUMMARY

To solve some or all problems existing in the prior art, embodiments of the present disclosure provide an air-conditioning system for a data center computer room and a control method thereof. The technical solutions are as follows.

In a first aspect, there is provided an air-conditioning system for a data center computer room, comprising an indoor evaporation circulation loop and an outdoor cooling circulation loop, where the indoor evaporation circulation loop comprises an evaporator and an indoor side heat exchange fan. The outdoor cooling circulation loop comprises the evaporator, an outdoor side heat exchange fan, a wet-film cooling cooler, a condenser, an intercooler, a low-pressure stage compressor, a high-pressure stage compressor, a one-way valve, and a refrigerant pipeline.

The indoor side heat exchange fan is arranged in front of the evaporator and is configured to provide power to indoor air, such that the indoor air flows through the evaporator.

The outdoor side heat exchange fan and the wet-film cooling cooler are arranged in front of the condenser, and the outdoor side heat exchange fan is configured to provide power to outdoor air, such that the outdoor air flows through the condenser and/or the wet-film cooling cooler.

The evaporator, the condenser, a primary side of the intercooler, the evaporator and the one-way valve are connected end to end in turn, where a primary side inlet of the intercooler is connected to the condenser, and a primary side outlet of the intercooler is connected to the evaporator.

The primary side outlet of the intercooler is further connected to an auxiliary side inlet of the intercooler, and an auxiliary side outlet of the intercooler is connected to the high-pressure stage compressor.

A two-stage compressor formed by series connection of the low-pressure stage compressor and the high-pressure stage compressor is connected in parallel to the one-way valve.

Alternatively, the indoor evaporation circulation loop further comprises an indoor air supply duct and an indoor air return duct, where the indoor air supply duct is configured to guide the indoor air from the evaporator to an IT device in the data center computer room, and the indoor air return duct is configured to guide the indoor air from the IT device into the evaporator.

Alternatively, the low-pressure stage compressor and the high-pressure stage compressor are air-floating centrifugal compressors.

Alternatively, the intercooler is a plate heat exchanger.

Alternatively, the outdoor side heat exchange fan is a variable-speed regulation axial flow fan.

Alternatively, the indoor side heat exchange fan is an electronic commutation fan.

Alternatively, the outdoor cooling circulation loop further comprises a refrigerant circulating pump, where the refrigerant circulating pump is a shielded pipeline centrifugal circulating pump and is arranged between the condenser and the intercooler.

A second aspect provides a control method for an air-conditioning system for a data center computer room, which is applied to the system of the first aspect. The method comprises:
adjusting a cooling power of a current cooling mode or switching the cooling mode according to an air supply temperature of the indoor evaporation circulation loop;
the cooling mode comprises:
a first cooling mode: turning on the condenser and the one-way valve, and turning off the wet-film cooling cooler and the two-stage compressor; where a refrigerant in the outdoor cooling circulation loop carries out heat exchange with the outdoor air through the condenser, enters the evaporator through the primary side of the intercooler after the heat exchange and cooling, carries out heat exchange with the indoor air in the indoor evaporation circulation loop, and enters the condenser again after evaporation;
a second cooling mode: turning on the condenser, the one-way valve and the wet-film cooling cooler, and turning off the two-stage compressor, where the wet-film cooling cooler precools the outdoor air before the outdoor air enters the condenser, the refrigerant in the outdoor cooling circulation loop enters the condenser to carry out heat exchange with the outdoor air, enters the evaporator through the primary side of the intercooler after the heat exchange and cooling, carries out heat exchange with the indoor air in the indoor evaporation circulation loop, and enters the condenser again after evaporation; and
a third cooling mode: turning on the condenser, the wet-film cooling cooler and the two-stage compressor, and turning off the one-way valve; where the wet-film cooling cooler precools the outdoor air before the outdoor air enters the condenser, the refrigerant in the outdoor cooling circulation loop enters the condenser to carry out heat exchange with the outdoor air; after the heat exchange and cooling, the refrigerant enters the primary side of the intercooler to carry out heat exchange with a refrigerant in the auxiliary side of the intercooler, and is divided into two paths after flowing out from the primary side outlet of the intercooler; a first path of the refrigerant enters the auxiliary side of the intercooler to carry out heat exchange with the refrigerant in the primary side of the intercooler, flows out from the auxiliary side outlet of the intercooler, mixes with the refrigerant discharged from the low-pressure stage compressor, and enters the high-pressure stage compressor; a second path of the refrigerant enters the evaporator, carries out heat exchange with the indoor air in the indoor evaporation circulation loop, enters the low-pressure stage compressor after evaporation, and enters the condenser after being compressed by the low-pressure stage compressor.

Alternatively, the adjusting a cooling power of a current cooling mode or switching the cooling mode according to an air supply temperature of the indoor evaporation circulation loop includes:
raising the cooling power of the current cooling mode when the air supply temperature is higher than a target temperature and the cooling power of the current cooling mode is less than a maximum cooling power of the current cooling mode; and
raising a cooling level of the current cooling mode when the air supply temperature is higher than the target temperature and the cooling power of the current cooling mode is equal to the maximum cooling power of the current cooling mode.

The cooling level of the first cooling mode, the cooling level of the second cooling mode and the cooling level of the third cooling mode are incremental.

Alternatively, the adjusting a cooling power of a current cooling mode or switching the cooling mode according to an air supply temperature of the indoor evaporation circulation loop includes:
lowering the cooling level of the current cooling mode when the air supply temperature is lower than the target temperature and the cooling power of the current cooling mode is greater than a minimum cooling power of the current cooling mode; and
lowering the cooling level of the current cooling mode when the air supply temperature is lower than the target temperature and the cooling power of the current cooling mode is equal to the minimum cooling power of the current cooling mode.

Alternatively, adjusting the cooling power of the current cooling mode in response to the current cooling mode being the first cooling mode or the second cooling mode comprises: adjusting an actual output power of the indoor side heat exchange fan and an actual output power of the outdoor side heat exchange fan; and
adjusting the cooling power of the current cooling mode in response to the current cooling mode being the third cooling mode comprises: adjusting the actual output power of the indoor side heat exchange fan, the actual output power of the outdoor side heat exchange fan, and an actual output power of the two-stage compressor.

The technical solutions provided by the embodiments of the present disclosure have the following beneficial effects.

The temperature of the data center computer room is adjusted by accurately using natural cold sources, to reduce time and load of mechanical refrigeration operation. The condenser is precooled by means of the wet-film cooling cooler, to reduce the condensing temperature of the refrigeration system and obtain higher refrigeration capacity and energy efficiency of the refrigeration system. By using two-stage compression oil-free air-floating centrifugal compressor technology with higher refrigeration efficiency, fine adjustment of the mechanical refrigeration is met, which only needs to use a small amount of water. Therefore, strict requirements of the data center computer room for air supply temperature are met, air-conditioning energy consumption in the data center computer room is reduced, and the consumption of water resources is reduced.

### BRIEF DESCRIPTION OF THE DRAWINGS

To describe the technical solutions in the embodiments of the present disclosure more clearly, the following will briefly introduce the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of an air-conditioning system for a data center computer room provided by an embodiment of the present disclosure;

FIG. 2 is a schematic structural diagram of an air-conditioning system for a data center computer room operating in a first cooling mode provided by an embodiment of the present disclosure;

FIG. 3 is a schematic structural diagram of an air-conditioning system for a data center computer room operating in a second cooling mode provided by an embodiment of the present disclosure; and

FIG. 4 is a schematic structural diagram of an air-conditioning system for a data center computer room operating in a third cooling mode provided by an embodiment of the present disclosure.

### REFERENCE NUMERALS IN THE ACCOMPANYING DRAWINGS

Outdoor side heat exchange fans 1 and 2; condenser 3; condenser inlet pipeline 4; wet-film cooling cooler 5; exhaust pipeline 6; connection pipelines 7, 11, 22, 24 and 26; two-stage compressor 8; one-way valve 9; suction pipeline 10; evaporator air return pipeline 12; indoor air supply channel 13; indoor side heat exchange fan 14; evaporator 15; IT device 16; indoor air return channel 17; refrigerant throttle rear pipeline 18; electronic expansion valve 19; solenoid valve 20; intercooler outlet pipe 21; solenoid valve 23; electronic expansion valve 25; intermediate air make-up pipe 27; refrigerant circulating pump outlet pipe 28; refrigerant circulating pump 29; outdoor side condenser outlet pipeline 30; and intercooler 31.

### DETAILED DESCRIPTION

To make the objectives, technical solutions and advantages of the present disclosure clearer, the embodiments of the present disclosure will be further described below in detail with reference to the accompanying drawings. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

Embodiments of the present disclosure provide an air-conditioning system for a data center computer room, which may include an indoor evaporation circulation loop and an outdoor cooling circulation loop, where the indoor evaporation circulation loop includes an evaporator and an indoor side heat exchange fan. The outdoor cooling circulation loop includes the evaporator, an outdoor side heat exchange fan, a wet-film cooling cooler, a condenser, an intercooler, a low-pressure stage compressor, a high-pressure stage compressor, a one-way valve, and a refrigerant pipeline.

In implementation, the indoor side heat exchange fan is arranged in front of the evaporator and is configured to provide power to indoor air, such that the indoor air flows through the evaporator. The outdoor side heat exchange fan and the wet-film cooling cooler are arranged in front of the condenser, and the outdoor side heat exchange fan is configured to provide power to outdoor air, such that the outdoor air flows through the condenser and/or the wet-film cooling cooler. The evaporator, the condenser, a primary side of the intercooler, the evaporator and the one-way valve are connected end to end in turn, where a primary side inlet of the intercooler is connected to the condenser, and a primary side outlet of the intercooler is connected to the evaporator; the primary side outlet of the intercooler is further connected to an auxiliary side inlet of the intercooler, and an auxiliary side outlet of the intercooler is connected to the high-pressure stage compressor. A two-stage compressor formed by series connection of the low-pressure stage compressor and the high-pressure stage compressor is connected in parallel to the one-way valve.

In implementation, the evaporator is configured to perform heat exchange between the indoor air in the indoor evaporation circulation loop and the refrigerant in the outdoor cooling circulation loop. The heat in the air around the evaporator is transferred to an outer wall of the evaporator tube through heat convection, and then to the inner wall of an evaporator tube through heat convection, and then is transferred to the refrigerant through heat convection, such that the refrigerant can absorb heat to evaporate or boil.

Further, the indoor evaporation circulation loop may further include an indoor air supply duct and an indoor air return duct, where the indoor air supply duct is configured to guide the indoor air from the evaporator to an IT device in the data center computer room, and the indoor air return duct is configured to guide the indoor air from the IT device into the evaporator.

In one embodiment, the low-pressure stage compressor and the high-pressure stage compressor are air-floating centrifugal compressors.

In implementation, in the present disclosure at least two compressors with different exhaust pressures are employed to compress the refrigerant gas, such a compressor set may be referred to as a two-stage compressor. The low-pressure stage compressor may be an air-bearing-based centrifugal compressor with an exhaust pressure of 1-10 MPa, and the high-pressure stage compressor may be an air-bearing-based centrifugal compressor with an exhaust pressure of 100-1000 MPa.

In one embodiment, the intercooler is a plate heat exchanger.

In implementation, the refrigerant may flow in a flow passage of the plate heat exchanger to exchange heat through plates.

In one embodiment, the outdoor side heat exchange fan may be a variable-speed regulation axial flow fan, and the indoor side heat exchange fan may be an electrical commutation (EC) fan.

In implementation, convection heat transfer is strengthened by increasing air volume of the heat exchange fan, which can improve the cooling effect.

In one embodiment, the outdoor cooling circulation loop further includes a refrigerant circulating pump, and the refrigerant circulating pump is a shielded pipeline centrifugal circulating pump and is arranged between the condenser and the intercooler.

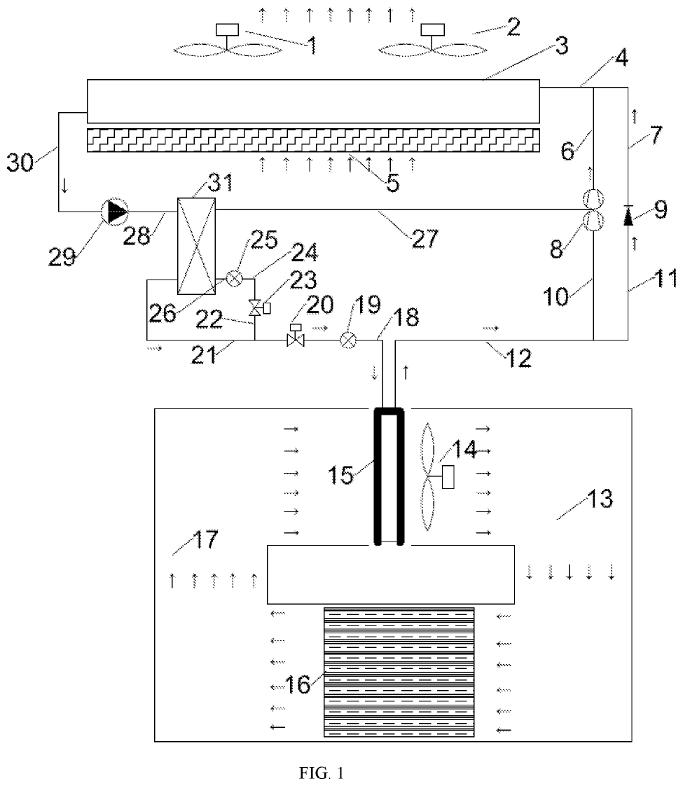

Based on the same technical concept, the embodiments of the present disclosure also provide a control method for an air-conditioning system for a data center computer room. The air-conditioning system for the data center computer room shown in FIGS. 1-4 will be described in detail below, and arrows in the figures may indicate flow directions of fluids.

Referring to FIG. 1, the air-conditioning system for the data center computer room provided by the present disclosure may include: outdoor side heat exchange fans 1 and 2; a condenser 3; a condenser inlet pipeline 4; a wet-film cooling cooler 5; an exhaust pipeline 6; connection pipelines 7, 11, 22, 24 and 26; a two-stage compressor 8; a one-way valve 9; a suction pipeline 10; an evaporator air return pipeline 12; an indoor air supply channel 13; an indoor side heat exchange fan 14; an evaporator 15; an IT device 16; an indoor air return channel 17; a refrigerant throttle rear pipeline 18; an electronic expansion valve 19; a solenoid valve 20; an intercooler outlet pipe 21; a solenoid valve 23; an electronic expansion valve 25; an intermediate air make-up pipe 27; a refrigerant circulating pump outlet pipe 28; a refrigerant circulating pump 29; an outdoor side condenser outlet pipeline 30; and an intercooler 31.

In implementation, number of the indoor/outdoor heat exchange fans may be one or more, which is not limited in the present disclosure.

When the air-conditioning system for the data center computer room is started for the first time, it may be operated in the first cooling mode. The condenser and the one-way valve are turned on, and the wet-film cooling cooler and the two-stage compressor are turned off. The refrigerant in the outdoor cooling circulation loop carries out heat exchange with the outdoor air through the condenser, enters the evaporator through the primary side of the intercooler after the heat exchange and cooling, carries out heat exchange with the indoor air in the indoor evaporation circulation loop, and enters the condenser again after evaporation.

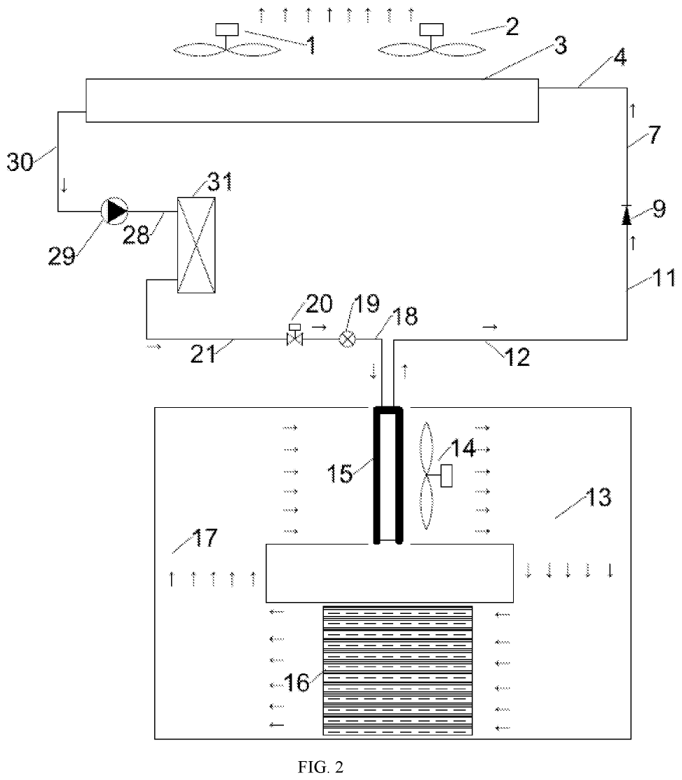

Referring to FIG. 2, guided by the indoor air return duct 17 and driven by the indoor heat exchange fan 14, hot air from the IT device 16 passes through the indoor evaporator 15. After heat exchange between the hot air in the indoor evaporator 15 and the refrigerant evaporated after throttling, cold air from the indoor evaporator 15 flows out through the indoor air supply duct, and is sent into the computer room through the indoor air supply channel 13 to cool the IT device 16. The refrigerant gas evaporated in the indoor evaporator flows, through the indoor evaporator air return pipeline 12, into the one-way valve 9, then flows into the condenser inlet pipeline 4 through the pipeline 7, and enters the outdoor condenser 3. By adjusting the outdoor side heat exchange fans 1 and 2, the refrigerant in the outdoor condenser is cooled, such that heat of the refrigerant is discharged into the atmosphere, and thus the cooled refrigerant is condensed from gas into liquid, where the refrigerant liquid passes through the outdoor side condenser outlet pipeline 30. After being adjusted and pressurized in the refrigerant circulating pump 29, the refrigerant flows through the primary side of the intercooler 31 (the auxiliary side of the intercooler 31 does not operate in this mode). Next, the refrigerant is sent to the solenoid valve 20 through the intercooler outlet pipe 21 and flows into the electronic expansion valve 19, and is throttled through the electronic expansion valve 19. The throttled refrigerant enters the indoor evaporator 15 through the refrigerant throttle rear pipeline 18 for evaporation, and the evaporated refrigerant passes through the air return pipeline 12 again. In this way, a complete refrigeration cycle is formed.

In implementation, the outdoor heat exchange fans 1 and 2 and the indoor side heat exchange fan 14 may be adjusted respectively according to the load of the indoor IT device 16 in the data center computer room, to obtain a stable target temperature of the indoor side, thereby reducing power consumption of the outdoor and indoor heat exchange fans. By cooling the refrigerant using natural cold sources, the target temperature needed by the indoor side can be obtained without starting the compressor, thus saving energy consumption.

It is worth mentioning that in the above-mentioned first cooling mode, to improve the cooling effect, the outdoor heat exchange fans 1 and 2 and the indoor side heat exchange fan 14 are respectively adjusted. Specifically, the air supply temperature of the indoor air supply channel is collected in real time, and it is determined whether the air supply temperature of the indoor air supply channel is higher than a preset target temperature. When the air supply temperature is higher than the target temperature, the air volume of the indoor/outdoor heat exchange fan may be raised, that is, the actual output power of the indoor/outdoor heat exchange fan is raised. The air supply temperature is still higher than the target temperature when the actual output power of the indoor/outdoor heat exchange fan is adjusted to the maximum. In this case, the air-conditioning system for the data center computer room may be switched to the second cooling mode.

Accordingly, when the cooling effect is better, to save energy, the air volume of the indoor/outdoor heat exchange fan may be lowered under the condition that the air supply temperature is not higher than the target temperature.

Further, when the outdoor air temperature rises and the load of the indoor IT device 16 increases, and when the outdoor fan is adjusted to the maximum load in the first cooling mode operation of the unit, the indoor air supply temperature is higher than the preset target temperature. In this case, a second cooling mode is entered. In the second cooling mode, the condenser, the one-way valve and the wet-film cooling cooler are turned on, and the two-stage compressor is turned off. The wet-film cooling cooler precools the outdoor air before the outdoor air enters the condenser, the refrigerant in the outdoor cooling circulation loop enters the condenser to carry out heat exchange with the outdoor air, enters the evaporator through the primary side of the intercooler after the heat exchange and cooling, carries out heat exchange with the indoor air in the indoor evaporation circulation loop, and enters the condenser again after evaporation.

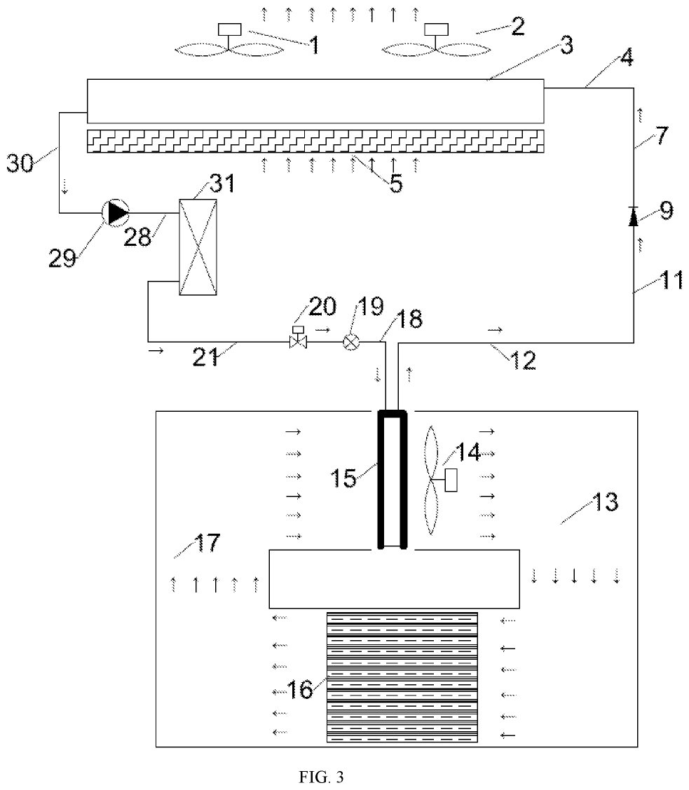

Referring to FIG. 3, guided by the indoor air return duct 17 and driven by the indoor heat exchange fan 14, hot air from the IT device 16 passes through the indoor evaporator 15. After heat exchange between the hot air in the indoor evaporator 15 and the refrigerant evaporated after throttling, cold air from the indoor evaporator 15 flows out through the indoor air supply duct, and is sent into the computer room through the indoor air supply channel 13 to cool the IT device 16. The refrigerant gas evaporated in the indoor evaporator flows, through the indoor evaporator air return pipeline 12, into the one-way valve 9, then flows into the condenser inlet pipeline 4 through the pipeline 7, and enters the outdoor condenser 3. Further, after the outdoor air is precooled by the wet-film cooling cooler 5, cold air below ambient temperature is obtained, and then the cold air enters the condenser 3 to cool the circulating refrigerant. By adjusting the outdoor side heat exchange fans 1 and 2, the refrigerant in the outdoor condenser is cooled, such that heat of the refrigerant is discharged into the atmosphere, and thus the cooled refrigerant is condensed from gas into liquid, where the refrigerant liquid passes through the outdoor side condenser outlet pipeline 30. After being adjusted and pressurized in the refrigerant circulating pump 29, the refrigerant flows through the primary side of the intercooler 31 (the auxiliary side of the intercooler 31 does not operate in this mode). Next, the refrigerant is sent to the solenoid valve 20 through the intercooler outlet pipe 21 and flows into the electronic expansion valve 19, and is throttled through the electronic expansion valve 19. The throttled refrigerant enters the indoor evaporator 15 through the refrigerant throttle rear pipeline 18 for evaporation, and the evaporated refrigerant passes through the air return pipeline 12 again. In this way, a complete refrigeration cycle is formed.

In implementation, the outdoor heat exchange fans 1 and 2 and the indoor side heat exchange fan 14 may be adjusted respectively according to the load of the indoor IT device 16 in the data center computer room, to obtain a stable target temperature of the indoor side, thereby reducing power consumption of the outdoor and indoor heat exchange fans. By cooling the refrigerant using natural cold sources, the target temperature needed by the indoor side can be obtained without starting the compressor, thus saving energy consumption.

It is worth mentioning that, similar to the above-mentioned first cooling mode, in the above-mentioned second cooling mode, to improve the cooling effect, the air supply temperature of the indoor air supply channel may be collected in real time, and it is determined whether the air supply temperature of the indoor air supply channel is higher than the preset target temperature. When the air supply temperature is higher than the target temperature, the air volume of the indoor/outdoor heat exchange fan may be raised, that is, the actual output power of the indoor/outdoor heat exchange fan is raised. The air supply temperature is still higher than the target temperature when the actual output power of the indoor/outdoor heat exchange fan is adjusted to the maximum. In this case, the air-conditioning system for the data center computer room may be switched to a third cooling mode.

Accordingly, when the cooling effect is better, to save energy, the air volume of the indoor/outdoor heat exchange fan may be lowered under the condition that the air supply temperature is not higher than the target temperature. The cooling effect still exceeds expectations when the power of the indoor/outdoor heat exchange fan is adjusted to the minimum. In this case, the air-conditioning system for the data center computer room may be switched back to the first cooling mode.

Further, when the outdoor air temperature rises and the load of the indoor IT device 16 increases, and when the outdoor fan is adjusted to the maximum load in the second cooling mode operation of the unit, the indoor air supply temperature is higher than the preset target temperature. In this case, the third cooling mode is entered. In the third cooling mode, the condenser, the wet-film cooling cooler and the two-stage compressor are turned on, and the one-way valve is turned off. The wet-film cooling cooler precools the outdoor air before the outdoor air enters the condenser, and the refrigerant in the outdoor cooling circulation loop enters the condenser to carry out heat exchange with the outdoor air. After the heat exchange and cooling, the refrigerant enters the primary side of the intercooler to carry out heat exchange with a refrigerant in the auxiliary side of the intercooler, and is divided into two paths after flowing out from the primary side outlet of the intercooler. A first path of the refrigerant enters the auxiliary side of the intercooler to carry out heat exchange with the refrigerant in the primary side of the intercooler, flows out from the auxiliary side outlet of the intercooler, mixes with the refrigerant discharged from the low-pressure stage compressor, and enters the high-pressure stage compressor. A second path of the refrigerant enters the evaporator, carries out heat exchange with the indoor air in the indoor evaporation circulation loop, enters the low-pressure stage compressor after evaporation, and enters the condenser after being compressed by the low-pressure stage compressor.

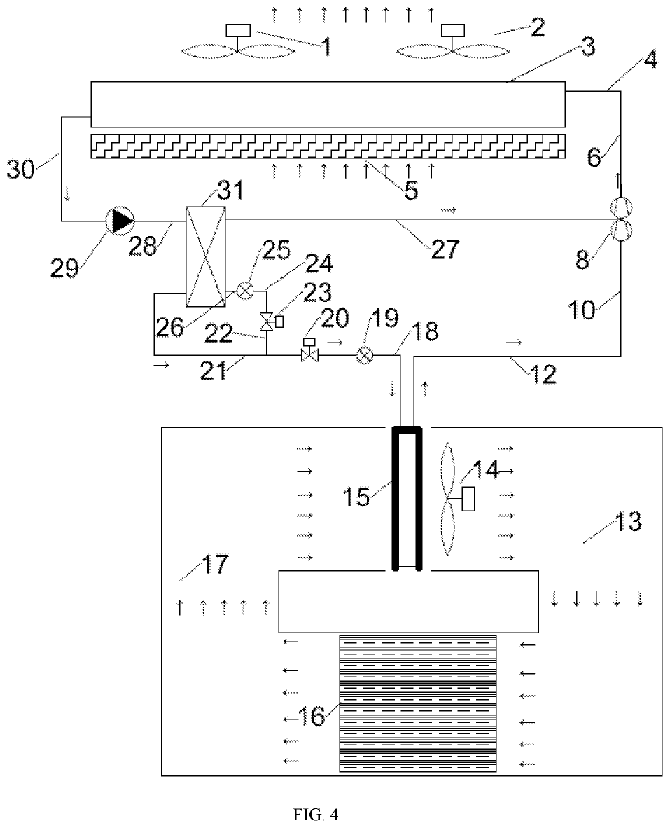

Referring to FIG. 4, guided by the indoor air return duct 17 and driven by the indoor heat exchange fan 14, hot air from the IT device 16 passes through the indoor evaporator 15. After heat exchange between the hot air in the indoor evaporator 15 and the refrigerant evaporated after throttling, cold air from the indoor evaporator 15 flows out through the indoor air supply duct, and is sent into the computer room through the indoor air supply channel 13 to cool the IT device 16. Refrigerant gas evaporated in the indoor evaporator flows, through the indoor evaporator air return pipeline 12, into a low-pressure stage inlet of the air-floating centrifugal compressor 8. After being compressed by the low-pressure stage compressor, the refrigerant gas is mixed with low-temperature refrigerant gas from the air make-up pipe 27. The low-temperature refrigerant in the air make-up pipe cools the superheated refrigerant gas discharged from the low-pressure stage, and specific volume of the cooled mixed gas becomes smaller, which is more beneficial to compression of the high-pressure stage compressor.

Further, the cooled mixed gas enters the high-pressure stage compressor for compression without increasing the power consumption of the high-pressure stage compressor, which obtains a larger refrigerant displacement compared with the compressor without intermediate air supply, thus increasing the refrigeration capacity of the system and improving refrigeration coefficient. The compressed refrigerant gas enters the condenser inlet pipeline 4 through the exhaust pipeline 6 and enters the outdoor condenser 3 for cooling.

Further, the outdoor air is precooled by the wet-film cooling cooler 5 to obtain cold air below the ambient temperature, and then enters the condenser 3 to cool the circulating refrigerant. By adjusting the outdoor side heat exchange fans 1 and 2, the refrigerant in the outdoor condenser is cooled, and the heat of the refrigerant is discharged into the atmosphere; the cooled refrigerant is condensed from gas to liquid, and flows through the outdoor side condenser outlet pipeline 30. After being adjusted and the pressurized in the refrigerant circulating pump 29, the refrigerant flows through the primary side of the intercooler 31 to carry out heat exchange with the refrigerant on the auxiliary side of the heat exchanger, which further reduces the temperature of the liquid on the primary side. The refrigerant is divided into two paths after flowing out from the primary side outlet pipe 21 of the intercooler 31.

One path of the refrigerant successively flows through the connection pipeline 22, the solenoid valve 23, the connection pipeline 24, and the electronic expansion valve 25. After being throttled and adjusted by the electronic expansion valve 25, the refrigerant flows through the pipeline 26 and enters the auxiliary side of the intercooler 31 for evaporation, and carries out heat exchange with the refrigerant on the primary side of the heat exchanger. The refrigerant gas evaporated from the auxiliary side enters an intermediate air make-up port of the air-floating compressor through the intermediate air make-up pipe 27, mixes with superheated gas discharged from the low-pressure stage of the air-floating compressor and cools the superheated gas, and then enters the high-pressure stage of the air-floating compressor for compression. Thus, by performing heat exchange and cooling on the refrigerant on the primary side of the intercooler 31, refrigerant liquid having a lower temperature may be obtained at the primary side outlet of the intercooler 31, thus increasing subcooling degree of the circulating refrigerant, and obtaining more refrigeration capacity without increasing the power consumption of the compressor.

The other path of the refrigerant flows into the electronic expansion valve 19 through the solenoid valve 20, and is throttled through the electronic expansion valve 19. The throttled refrigerant enters the indoor evaporator 15 through the refrigerant throttle rear pipeline 18 for evaporation, and the evaporated refrigerant passes through the air return pipeline 12 again, and then enters the air-floating centrifugal compressor 8 for compression. In this way, a complete refrigeration cycle is formed.

In implementation, the outdoor heat exchange fans 1 and 2, the indoor side heat exchange fan 14 and the two-stage air-floating centrifugal compressor may be adjusted respectively according to the load of the indoor IT device 16 in the data center computer room, to obtain a stable target temperature of the indoor side, thereby reducing power consumption for the outdoor and indoor heat exchange fans and the air-floating centrifugal compressor. The wet-film cooling cooler is employed to precool the air entering the condenser, to reduce the condensation temperature of the refrigeration system, and the intercooler is employed to obtain greater subcooling degree of the circulating refrigerant, which increases the refrigeration capacity of the circulating system, improves the gas transmission coefficient of the compressor through intermediate air make-up cooling, and reduces the power consumption of the compressor, thus greatly improving the energy efficiency and reducing the power consumption for the refrigeration system. In this way, the target temperature required for the indoor side can be obtained, and energy consumption can be saved.

It is worth mentioning that in the above-mentioned third cooling mode, to improve the cooling effect, the air supply temperature of the indoor air supply channel may be collected in real time, and it is determined whether the air supply temperature of the indoor air supply channel is higher than a preset target temperature. When the air supply temperature is higher than the target temperature, the air volume of the indoor/outdoor heat exchange fan may be increased, that is, the actual output power of the indoor/outdoor heat exchange fan is raised. In addition, the actual output power of the two-stage air-floating centrifugal compressor may also be raised.

Accordingly, when the cooling effect is better, to save energy, the actual output power of the indoor/outdoor heat exchange fan and the actual output power of the two-stage air-floating centrifugal compressor may be lowered under the condition that the air supply temperature is not higher than the target temperature. The cooling effect still exceeds expectations when the actual output power of the indoor/outdoor heat exchange fan and the actual output power of the two-stage air-floating centrifugal compressor are adjusted to the minimum. In this case, the air-conditioning system for the data center computer room may be switched back to the second cooling mode.

By adopting the air-conditioning system for the data center computer room and the control method thereof, the present disclosure can at least produce the following technical effects.

The temperature of the data center computer room is adjusted by accurately using natural cold sources, to reduce time and load of mechanical refrigeration operation. The condenser is precooled by means of the wet-film cooling cooler, to reduce the condensing temperature of the refrigeration system and obtain higher refrigeration capacity and energy efficiency of the refrigeration system. By using two-stage compression oil-free air-floating centrifugal compressor technology with higher refrigeration efficiency, fine adjustment of the mechanical refrigeration is met, which only needs to use a small amount of water. Therefore, strict requirements of the data center computer room for air supply temperature are met, air-conditioning energy consumption in the data center computer room is reduced, and the consumption of water resources is reduced.

The embodiments described above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. An air-conditioning system for a data center computer room comprising an indoor evaporation circulation loop and an outdoor cooling circulation loop, wherein the indoor evaporation circulation loop comprises an evaporator and an indoor side heat exchange fan; the outdoor cooling circulation loop comprises the evaporator, an outdoor side heat exchange fan, a wet-film cooling cooler, a condenser, an intercooler, a low-pressure stage compressor, a high-pressure stage compressor, a one-way valve, and a refrigerant pipeline;
the indoor side heat exchange fan is arranged in front of the evaporator and is configured to provide power to indoor air, such that the indoor air flows through the evaporator;
the outdoor side heat exchange fan and the wet-film cooling cooler are arranged in front of the condenser, and the outdoor side heat exchange fan is configured to provide power to outdoor air, such that the outdoor air flows through the condenser and/or the wet-film cooling cooler;
the evaporator, the condenser, a primary side of the intercooler, the evaporator and the one-way valve are connected end to end in turn, wherein a primary side inlet of the intercooler is connected to the condenser, and a primary side outlet of the intercooler is connected to the evaporator;
the primary side outlet of the intercooler is further connected to an auxiliary side inlet of the intercooler, and an auxiliary side outlet of the intercooler is connected to the high-pressure stage compressor; and
a two-stage compressor formed by series connection of the low-pressure stage compressor and the high-pressure stage compressor is connected in parallel to the one-way valve.

2. The air-conditioning system for the data center computer room according to claim 1, wherein the indoor evaporation circulation loop further comprises an indoor air supply duct and an indoor air return duct, the indoor air supply duct is configured to guide the indoor air from the evaporator to an IT device in the data center computer room, and the indoor air return duct is configured to guide the indoor air from the IT device into the evaporator.

3. The air-conditioning system for the data center computer room according to claim 1, wherein the low-pressure stage compressor and the high-pressure stage compressor are air-floating centrifugal compressors.

4. The air-conditioning system for the data center computer room according to claim 1, wherein the intercooler is a plate heat exchanger.

5. The air-conditioning system for the data center computer room according to claim 1, wherein the outdoor side heat exchange fan is a variable-speed regulation axial flow fan.

6. The air-conditioning system for the data center computer room according to claim 1, wherein the indoor side heat exchange fan is an electronic commutation fan.

7. The air-conditioning system for the data center computer room according to claim 1, wherein the outdoor cooling circulation loop further comprises a refrigerant circulating pump, the refrigerant circulating pump being a shielded pipeline centrifugal circulating pump and being arranged between the condenser and the intercooler.

8. A control method for an air-conditioning system for a data center computer room, wherein the air-conditioning system comprises an indoor evaporation circulation loop and an outdoor cooling circulation loop, wherein the indoor evaporation circulation loop comprises an evaporator and an indoor side heat exchange fan; the outdoor cooling circulation loop comprises the evaporator, an outdoor side heat exchange fan, a wet-film cooling cooler, a condenser, an intercooler, a low-pressure stage compressor, a high-pressure stage compressor, a one-way valve, and a refrigerant pipeline, the method comprising:
adjusting a cooling power of a current cooling mode or switching the cooling mode according to an air supply temperature of the indoor evaporation circulation loop;
the cooling mode comprises:
a first cooling mode: turning on the condenser and the one-way valve, and turning off the wet-film cooling cooler and the two-stage compressor; wherein a refrigerant in the outdoor cooling circulation loop carries out heat exchange with the outdoor air through the condenser, enters the evaporator through the primary side of the intercooler after the heat exchange and cooling, carries out heat exchange with the indoor air in the indoor evaporation circulation loop, and enters the condenser again after evaporation;
a second cooling mode: turning on the condenser, the one-way valve and the wet-film cooling cooler, and turning off the two-stage compressor, wherein the wet-film cooling cooler precools the outdoor air before the outdoor air enters the condenser, the refrigerant in the outdoor cooling circulation loop enters the condenser to carry out heat exchange with the outdoor air, enters the evaporator through the primary side of the intercooler after the heat exchange and cooling, carries out heat exchange with the indoor air in the indoor evaporation circulation loop, and enters the condenser again after evaporation; and
a third cooling mode: turning on the condenser, the wet-film cooling cooler and the two-stage compressor, and turning off the one-way valve; wherein the wet-film cooling cooler precools the outdoor air before the outdoor air enters the condenser, the refrigerant in the outdoor cooling circulation loop enters the condenser to carry out heat exchange with the outdoor air; after the heat exchange and cooling, the refrigerant enters the primary side of the intercooler to carry out heat exchange with a refrigerant in the auxiliary side of the intercooler, and is divided into two paths after flowing out from the primary side outlet of the intercooler; a first path of the refrigerant enters the auxiliary side of the intercooler to carry out heat exchange with the refrigerant in the primary side of the intercooler, flows out from the auxiliary side outlet of the intercooler, mixes with the refrigerant discharged from the low-pressure stage compressor, and enters the high-pressure stage compressor; a second path of the refrigerant enters the evaporator, carries out heat exchange with the indoor air in the indoor evaporation circulation loop, enters the low-pressure stage compressor after evaporation, and enters the condenser after being compressed by the low-pressure stage compressor.

9. The method according to claim 8, wherein the adjusting a cooling power of a current cooling mode or switching the cooling mode according to an air supply temperature of the indoor evaporation circulation loop comprises:
raising the cooling power of the current cooling mode when the air supply temperature is higher than a target temperature and the cooling power of the current cooling mode is less than a maximum cooling power of the current cooling mode; and
raising a cooling level of the current cooling mode when the air supply temperature is higher than the target temperature and the cooling power of the current cooling mode is equal to the maximum cooling power of the current cooling mode;
wherein the cooling level of the first cooling mode, the cooling level of the second cooling mode and the cooling level of the third cooling mode are incremental.

10. The method according to claim 9, wherein the adjusting a cooling power of a current cooling mode or switching the cooling mode according to an air supply temperature of the indoor evaporation circulation loop further comprises:
lowering the cooling level of the current cooling mode when the air supply temperature is lower than the target temperature and the cooling power of the current cooling mode is greater than a minimum cooling power of the current cooling mode; and
lowering the cooling level of the current cooling mode when the air supply temperature is lower than the target temperature and the cooling power of the current cooling mode is equal to the minimum cooling power of the current cooling mode.

11. The method according to claim 8, wherein adjusting the cooling power of the current cooling mode in response to the current cooling mode being the first cooling mode or the second cooling mode comprises: adjusting an actual output power of the indoor side heat exchange fan and an actual output power of the outdoor side heat exchange fan; and
adjusting the cooling power of the current cooling mode in response to the current cooling mode being the third cooling mode comprises: adjusting the actual output power of the indoor side heat exchange fan, the actual output power of the outdoor side heat exchange fan, and an actual output power of the two-stage compressor.
